(19) United States
(12) Patent Application Publication
(10) Pub. No.: US 2025/0297965 A1
(43) Pub. Date: Sep. 25, 2025

(54) CALIBRATION OF THE TILT ANGLE OF AN INCIDENT BEAM OF AN EXAMINATION SYSTEM

(71) Applicant: Applied Materials Israel Ltd., Rehovot (IL)

(72) Inventors: Jui-Kang CHUANG, Zhubei City (TW); Chun-Hsiang YEN, Hsinchu City (TW); Sandeep MEHTA, Taipei City (TW)

(21) Appl. No.: 18/610,135

(22) Filed: Mar. 19, 2024

(51) Int. Cl. G01N 21/93; G01N 21/88; G01N 21/95

(52) U.S. Cl. CPC G01N 21/93; G01N 21/8851; G01N 21/9501

(57) ABSTRACT

There are provided systems and methods comprising obtaining a set of images of a target, wherein the set of images has been acquired by an examination system operative to transmit a beam towards the target, wherein a first image of the set of images has been acquired capturing the target at a first height position, and a second image of the set of images has been acquired capturing the target at a second height position, different from the first height position, determining data D_{ΔZ} informative of a displacement of the target in the set of images, and using the data D_{ΔZ} and data informative of the first and second height positions to determine a stray tilt angle of a beam of the examination system.

### TECHNICAL FIELD

The presently disclosed subject matter relates, in general, to the field of examination of a specimen, and more specifically, to automating the examination of a specimen.

### BACKGROUND

Current demands for high density and performance associated with ultra large-scale integration of fabricated devices require submicron features, increased transistor and circuit speeds, and improved reliability. Such demands require formation of device features with high precision and uniformity, which, in turn, necessitates careful monitoring of the fabrication process, including automated examination of the devices while they are still in the form of semiconductor wafers.

Examination processes are used at various steps during semiconductor fabrication, and can include metrology measurements (e.g., critical dimension measurements, etc.).

### GENERAL DESCRIPTION

In accordance with certain aspects of the presently disclosed subject matter, there is provided a system comprising one or more processing circuitries configured to obtain a set of images of a target, wherein the set of images has been acquired by an examination system, wherein a first image of the set of images has been acquired capturing the target at a first height position, and a second image of the set of images has been acquired capturing the target at a second height position, different from the first height position, determine data D_{ΔZ} informative of a displacement of the target in the set of images, and use the data D_{ΔZ} and data informative of the first and second height positions to determine a stray tilt angle of a beam of the examination system.

According to some embodiments, the set of images has been obtained after a calibration of the beam of the examination system with respect to an objective lens of the examination system, wherein said calibration uses said target.

According to some embodiments, the calibration comprises aligning a focal point of the beam with an axis of symmetry of the objective lens, according to a matching criterion.

According to some embodiments, said calibration is associated with an accuracy equal to or smaller than 0.2 nm.

According to some embodiments, the set of images comprises images I₁ to I_{N}, with N≥2, wherein each image Iᵢ of the set of images has been acquired capturing the target at a height position Hi which differs from a height position Hⱼ at which other images Iⱼ of the set of images have been acquired, with i different from j.

According to some embodiments, the system is configured to use a geometrical relationship between the stray tilt angle, the data D_{ΔZ} informative of a displacement of the target in the set of images, and data informative of the first and second height positions, to determine said stray tilt angle.

According to some embodiments, the examination system comprises an element operative to move the target along a height direction, wherein the system is configured to use a model to compensate, at least partially, an error in said estimate of the stray tilt angle, caused at least by a motion of said element along a direction different from the height direction.

According to some embodiments, the examination system comprises a basement comprising an area dedicated to receiving a specimen under examination, wherein the target is located on the basement, or on a portion coupled to the basement.

According to some embodiments, the examination system comprises a basement comprising an area dedicated to receiving a specimen under examination, wherein the target is permanently located on the basement, or on a portion coupled to the basement.

According to some embodiments, the system is configured to control the examination system to switch between a first mode and a second mode, wherein, in the first mode, the beam is oriented towards the target to determine the stray tilt angle, and in the second mode, the beam is oriented towards the specimen for its examination, wherein the target and the specimen are associated with the same basement (that is to say that the target is located on the basement, or on a portion coupled to the basement, and the specimen is located on the basement, or on a portion coupled to the basement).

According to some embodiments, the examination system is operative to switch between a first mode and a second mode, wherein, in the first mode, the beam is oriented towards the target to determine the stray tilt angle, and in the second mode, the beam is oriented towards the specimen for its examination wherein the target and the specimen are associated with the same basement (that is to say that the target is located on the basement, or on a portion coupled to the basement, and the specimen is located on the basement, or on a portion coupled to the basement).

According to some embodiments, the target has a flat pattern.

According to some embodiments, the system is configured to use the data D_{ΔZ} and data informative of the first and second height positions to determine a first estimate of the stray tilt angle of the beam of the examination system, and use a model and the first estimate to generate said estimate of the stray tilt angle.

According to some embodiments, the model models an error of an estimate of the stray tilt angle, when said estimate is obtained based on height variation of the target and displacement of the target in images associated with said height variation.

According to some embodiments, the model models a relationship between estimated stray tilt angles of a plurality of stray tilt angles and a plurality of ground truth values of said plurality of stray tilt angles.

According to some embodiments, the system is configured to use a distance measurement device to determine data informative of a height position of the target.

According to some embodiments, the system is configured to, for each given stray tilt angle of the beam of the examination system, of a plurality of stray tilt angles, obtain a given set of images of the target, wherein a given first image of the given set of images has been acquired capturing the target at a given first height position, and a second image of the given set of images has been acquired capturing the target at a given second height position, different from the first height position, determine data D_{ΔZ, calibration} informative of a displacement of the target in the given set of images, and use the data D_{ΔZ, calibration} and data informative of the given first and second height positions to determine a given estimated stray tilt angle of the beam of the examination system, thereby obtaining a plurality of estimated stray tilt angles of the plurality of stray tilt angles, and use the plurality of stray tilt angles, or ground truth values of said plurality of stray tilt values, and the plurality of estimated stray tilt angles to generate a model.

According to some embodiments, the system is configured to use the data D_{ΔZ} and data informative of the first and second height positions to determine a first estimate of the stray tilt angle of the beam of the examination system and use the model and the first estimate to generate said estimate of the stray tilt angle.

According to some embodiments, the ground truth stray tilt angles values have been obtained using a wafer with a height profile including a first slope and a second slope.

In accordance with certain aspects of the presently disclosed subject matter, there is provided a method comprising one or more processing circuitries performing one or more of the features described with respect to the system (these features are therefore not repeated).

In accordance with other aspects of the presently disclosed subject matter, there is provided a non-transitory computer readable medium comprising instructions that, when executed by one or more processing circuitries, cause the one or more processing circuitries to perform operations or implement features as described with respect to the system (these features are therefore not repeated).

In accordance with other aspects of the presently disclosed subject matter, there is provided a system comprising one or more processing circuitries configured to, for each given stray tilt angle of a beam of an examination system, of a plurality of stray tilt angles, obtain a given set of images of the target, wherein a given first image of the given set of images has been acquired capturing the target at a given first height position, and a second image of the given set of images has been acquired capturing the target at a given second height position, different from the first height position, determine data D_{ΔZ, calibration} informative of a displacement of the target in the given set of images, and use the data D_{ΔZ, calibration} and data informative of the given first and second height positions to determine a given estimated stray tilt angle of the electron beam, thereby obtaining a plurality of estimated stray tilt angles of the plurality of stray tilt angles, and use the plurality of stray tilt angles, or ground truth values of said plurality of stray tilt values, and the plurality of estimated stray tilt angles to generate a model.

According to some embodiments, the system is configured to obtain a set of images of the target, wherein the set of images has been acquired by the examination system, wherein a first image of the set of images has been acquired capturing the target at a first height position, and a second image of the set of images has been acquired capturing the target at a second height position, different from the first height position, determine data D_{ΔZ} informative of a displacement of the target in the set of images, use the data D_{ΔZ} and data informative of the first and second height positions to determine a first estimate of a stray tilt angle of a beam of the examination system, and use the model and the first estimate to generate a second estimate of the stray tilt angle.

In accordance with certain aspects of the presently disclosed subject matter, there is provided a method comprising one or more processing circuitries performing one or more of the features described with respect to the system (these features are therefore not repeated).

In accordance with other aspects of the presently disclosed subject matter, there is provided a non-transitory computer readable medium comprising instructions that, when executed by one or more processing circuitries, cause the one or more processing circuitries to perform operations or implement features as described with respect to the system (these features are therefore not repeated).

The proposed solution provides various technical advantages. At least some of them are listed hereinafter.

According to some examples, the proposed solution is able to determine the stray tilt angle without using a tilt wafer (a wafer with one or more slopes).

According to some examples, the proposed solution is able to determine the stray tilt angle without requiring loading a tilt wafer each time the stray tilt angle has to be measured. The method is therefore time efficient and cost efficient. The area of the examination system, dedicated for receiving a wafer under examination, remains available, which facilitates a real-time switch between the metrology operations and determination of the stray tilt angle.

According to some examples, the proposed solution is able to determine the stray tilt angle in a quick and efficient way.

According to some examples, the proposed solution is able to determine accurately the stray tilt angle.

According to some examples, by virtue of the accurate determination of the stray tilt angle, metrology measurements (e.g., measurement of CD, overlay matching) are more accurate.

According to some examples, the proposed solution is able to correct error(s) in the determination of the stray tilt angle, which may be induced by a height motion of a target.

### BRIEF DESCRIPTION OF THE DRAWINGS

In order to understand the disclosure and to see how it may be carried out in practice, embodiments will now be described, by way of non-limiting example only, with reference to the accompanying drawings, which are presented hereinafter.

FIG. 1 illustrates a generalized block diagram of an examination system, in accordance with certain examples of the presently disclosed subject matter.

FIG. 2 illustrates a generalized flow-chart of a method of determining the stray tilt angle of the beam of an examination system, in accordance with certain examples of the presently disclosed subject matter.

FIG. 3A illustrates a non-limitative example of the acquisition of a target at a first height position.

FIG. 3B illustrates a non-limitative example of the acquisition of a target at a second height position.

FIG. 4A illustrates a non-limitative example of an image of the target in the configuration of FIG. 3A.

FIG. 4B illustrates a non-limitative example of an image of the target in the configuration of FIG. 3B.

FIG. 5 provides explanations of the displacement of a target in a set of images acquired for different height positions of the target.

FIG. 6 illustrates a non-limitative example of a target located on the same basement as a wafer under examination.

FIG. 7A illustrates a generalized flow-chart of a method of determining the stray tilt angle of a beam of an examination system, using the architecture of FIG. 6, in accordance with certain examples of the presently disclosed subject matter.

FIG. 7B illustrates an architecture which can be used to perform the method of FIG. 7A.

FIG. 8A illustrates a non-limitative example of an electron beam examination system including an objective lens.

FIG. 8B illustrates a non-limitative example of an uncalibrated state of the electron beam with respect to the objective lens.

FIG. 8C illustrates a non-limitative example of a calibrated state of the electron beam with respect to the objective lens.

FIG. 9 illustrates a generalized flow-chart of a method of calibrating the position of an electron beam with respect to an objective lens of the electron beam examination system, followed by a determination of the stray tilt angle, in accordance with certain examples of the presently disclosed subject matter.

FIG. 10 illustrates a non-limitative example of an undesired lateral displacement of a basement on which a target is located, when the basement undergoes height variation.

FIG. 11 illustrates a generalized flow-chart of a method of generating a model usable to correct error(s) in the estimate of the stray tilt angle, in accordance with certain examples of the presently disclosed subject matter.

FIG. 12 illustrates a non-limitative example of a tilt wafer usable to determine ground truth values of the stray tilt angles, usable in the method of FIG. 11.

FIG. 13 illustrates a non-limitative example of a model generated by the method of FIG. 11.

FIG. 14 illustrates a generalized flow-chart of a method of using the method of FIG. 11 to correct error(s) in the estimate of the stray tilt angle, in accordance with certain examples of the presently disclosed subject matter.

FIG. 15 illustrates a non-limitative example of the method of FIG. 14.

FIG. 16 illustrates a generalized flow-chart of a method of determining height position data of a target, in accordance with certain examples of the presently disclosed subject matter.

### DETAILED DESCRIPTION OF EMBODIMENTS

The stray tilt angle is the amount of unintended angular deviation of a beam (such as an electron beam) from a desired direction. The desired direction can correspond for example to the normal to the specimen's (wafer) surface. New methods and systems of measuring the stray tilt angle are proposed hereinafter. In accordance with certain examples of the presently disclosed subject matter, different images of a target are acquired, for different height positions of the target. By virtue of the height variation of the target, the position of the target changes in the different images. A geometrical relationship linking the amount of displacement of the target in the different images, the variation in the height position of the target, and the stray tilt angle, is used to determine an estimate of the stray tilt angle.

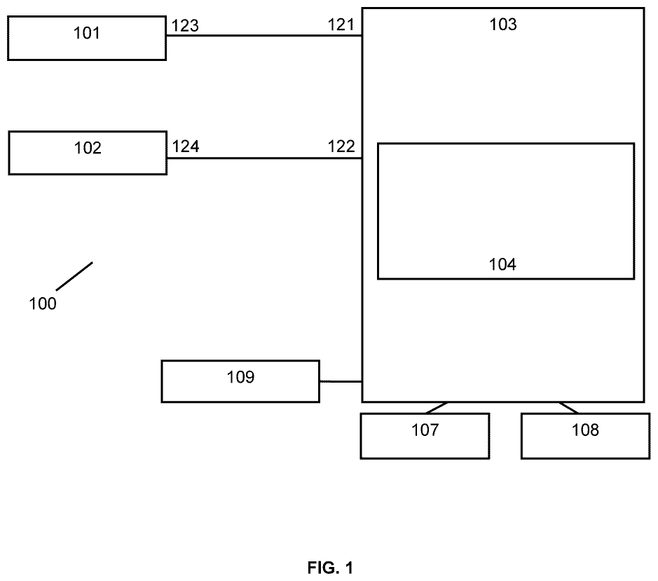

Attention is drawn to FIG. 1 illustrating a functional block diagram of an examination system 100 in accordance with certain examples of the presently disclosed subject matter. The examination system 100 illustrated in FIG. 1 can be used for examination of a specimen (e.g., of a wafer and/or parts thereof) as part of the specimen fabrication process. The illustrated examination system 100 comprises computer-based system 103. System 103 can be operatively connected to one or more low-resolution examination tools 101 and/or one or more high-resolution examination tools 102 and/or other examination tools. The examination tools are configured to capture images and/or to review the captured image(s) and/or to enable or provide measurements related to the captured image(s).

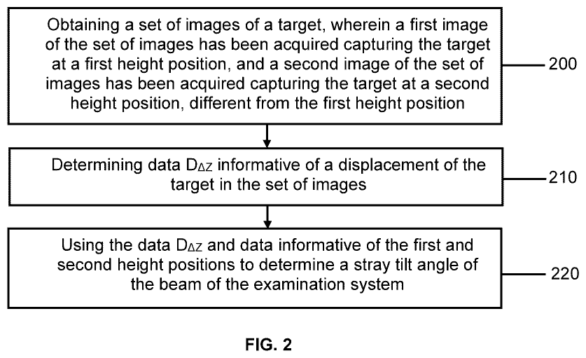

System 103 includes a processing circuitry 104, which includes one or more processors and one or more memories. The processing circuitry 104 is configured to provide all processing necessary for operating the system 103 as further detailed hereinafter (see methods described in FIGS. 2, 7A, 9, 11, 14, and 16 which can be performed at least partially by system 103 and/or system 100).

System 103 is configured to receive input data. Input data can include data (and/or derivatives thereof and/or metadata associated therewith) produced by the examination tools and/or data produced and/or stored in one or more data repositories 109. It is noted that input data can include images (e.g., captured images, images derived from the captured images, simulated images, synthetic images, etc.) and associated numeric data (e.g., metadata, hand-crafted attributes, etc.). It is further noted that image data can include data related to a layer of interest and/or to one or more other layers of the specimen.

By way of non-limiting example, a specimen can be examined by one or more low-resolution examination machines 101 (e.g., an optical inspection system, low-resolution SEM, etc.). The resulting data (low-resolution image data 121), informative of low-resolution images of the specimen, can be transmitted—directly or via one or more intermediate systems—to system 103. Alternatively, or additionally, the specimen can be examined by a high-resolution machine 102, such as a scanning electron microscope (SEM), an Atomic Force Microscopy (AFM), or an optical examination tool (such as, but not limited to, Enlight Optical Inspection System of the Applicant). The resulting data (high-resolution image data 122) informative of high-resolution images of the specimen, can be transmitted—directly, or via one or more intermediate systems—to system 103.

It is noted that image data can be received and processed together with metadata (e.g., pixel size, text description of defect type, parameters of image capturing process, etc.) associated therewith.

Upon processing the input data (e.g. low-resolution image data and/or high-resolution image data, together with other data as, for example, design data, synthetic data, etc.), system 103 can send instructions 123 and/or 124 to any of the examination tool(s), store the results (such as data informative of the stray tilt angle) in a storage system 107, render the results via a computer-based graphical user interface GUI 108 and/or send the results to an external system.

Those versed in the art will readily appreciate that the teachings of the presently disclosed subject matter are not bound by the system illustrated in FIG. 1; equivalent and/or modified functionality can be consolidated or divided in another manner and can be implemented in any appropriate combination of software with firmware and/or hardware.

Without limiting the scope of the disclosure in any way, it should also be noted that the examination tools can be implemented as inspection machines of various types, such as optical imaging machines, electron beam inspection machines, and so on. In some cases, the same examination tool can provide low-resolution image data and high-resolution image data. In some cases, at least one examination tool can have metrology capabilities.

It is noted that the examination system illustrated in FIG. 1 can be implemented in a distributed computing environment, in which the aforementioned functional modules shown in FIG. 1 can be distributed over several local and/or remote devices, and can be linked through a communication network. It is further noted that in other embodiments at least some examination tools 101 and/or 102, data repositories 109, storage system 107 can be external to the examination system 100 and operate in data communication with system 103. System 103 can be implemented as stand-alone computer(s) to be used in conjunction with the examination tools. Alternatively, the respective functions of the system can, at least partly, be integrated with one or more examination tools.

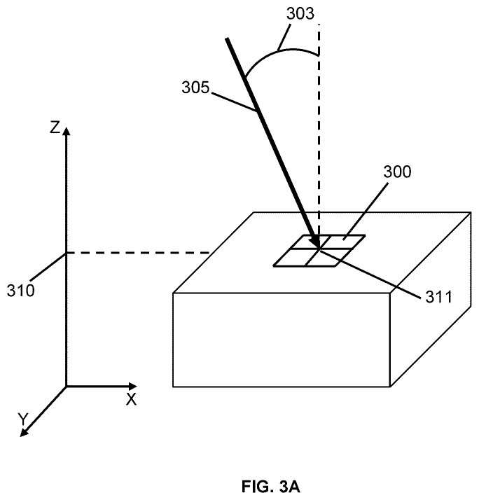

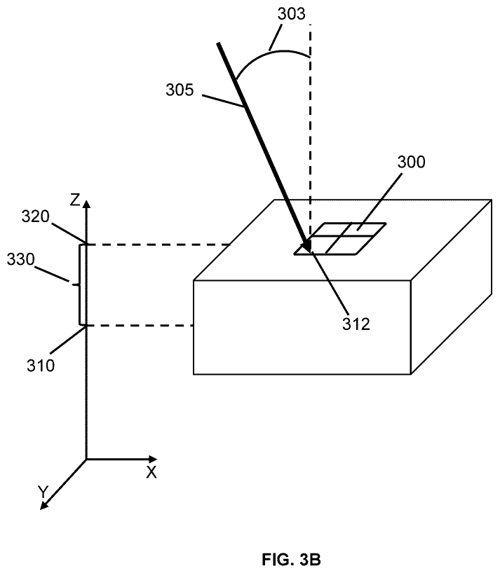

Attention is now drawn to FIGS. 2, 3A, and 3B.

The method of FIG. 2 includes obtaining (operation 200) a set of images of a target 300. The set of images has been acquired by an examination system, such as the examination system 101 or 102, operative to transmit a beam towards the target. The examination system can correspond to an electron beam examination system (in this case, the beam is an electron beam), or to an optical examination system (in this case, the beam is an optical beam). The target 300 can correspond e.g. to a specimen including one or more patterns. Non-limitative examples of targets are provided hereinafter.

The set of images includes at least two images. In some examples, the set of images can include more than two images. A first image of the target 300 has been acquired capturing the target 300 located at a first height position 310. The height position can be measured along a vertical axis (Z axis), or along an axis orthogonal to the plane of the specimen (which can coincide with the vertical Z axis).

A second image of the target 300 has been acquired capturing the target 300 at a second height position 320, different from the first height position 310.

The height difference AZ between the first height position 310 and the second height position 320 is noted 330 in FIG. 3B.

As visible in FIGS. 3A and 3B, due to the displacement of the target 300 along the vertical axis between acquisition of the first image and acquisition of the second image, the beam 305 (which can correspond to an electron beam, or to an optical beam, depending on the type of examination system) impacts the target 300 at a different position. In FIG. 3A, the beam 305 impacts the target 300 at a first area 311 and in FIG. 3B, the beam 305 impacts the target 300 at a second area 312, different from the first area 311. Note that the same principles apply to an optical examination system.

Therefore, the first position of the target 300 in the first image differs from the second position of the target 300 in the second image. The first position can differ from the second position by a translation along the axis X (horizontal axis in the plane of the specimen) and/or along the axis Y (vertical axis in the plane of the specimen).

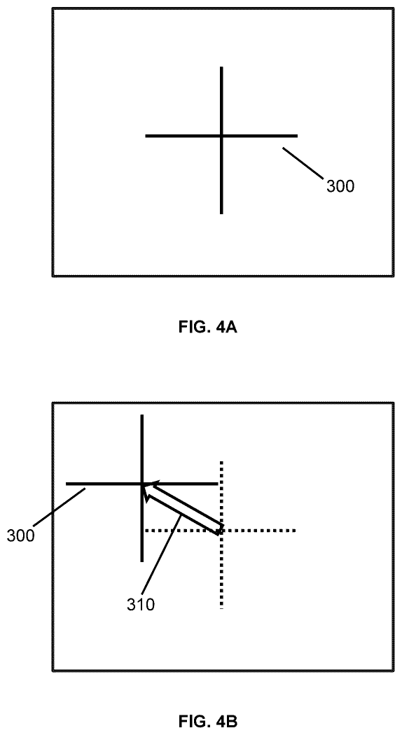

A non-limitative example of the displacement of the position of the target 300 in the images is illustrated in FIGS. 4A and 4B. In FIG. 4A, the target 300 is located at a first position. In FIG. 4B, the target 300 is located at a second position. The displacement of the target 300 between the two positions is represented by the vector 310.

The method of FIG. 2 further includes (operation 210) determining data DAz informative of a displacement of the target in the set of images. In particular, operation 210 can include determining a first displacement of the target between the first image and the second image along the X axis (horizontal axis of the images) and a second displacement of the target between the first image and the second image along the Y axis (vertical axis of the images).

In order to determine the displacement of the target, various methods can be used. In some examples, the first image can be correlated to the second image. This correlation enables determining the displacement of the target between the first image and the second image. In some examples, the first image and/or the second image can be correlated to template image(s) to determine the position of the target.

In some examples, an image processing algorithm (also called pattern recognition algorithm) can be used to identify the target in the first image and in the second image. Once the position of the target in the first image and the position of the target in the second image have been identified, the displacement of the target can be determined. The image processing algorithm can include a machine learning model, such as a deep neural network (trained to detect the target). Examples of deep neural networks include Convolutional Neural Networks, Recurrent Neural Networks, etc. These examples are not limitative. The training can be performed using methods such as Backpropagation. This training can be supervised (a training set with labelled training images of the target can be used for this training, the label being indicative of the position of the target in the training images), or unsupervised.

The method of FIG. 2 further includes (operation 220) using the data D_{ΔZ} and data informative of the first and second height positions to determine a stray tilt angle of the beam of the examination system. As mentioned above, this can correspond to the stray tilt angle of the electron beam of an electron beam examination system, or to the stray tilt angle of the optical beam of an optical examination system.

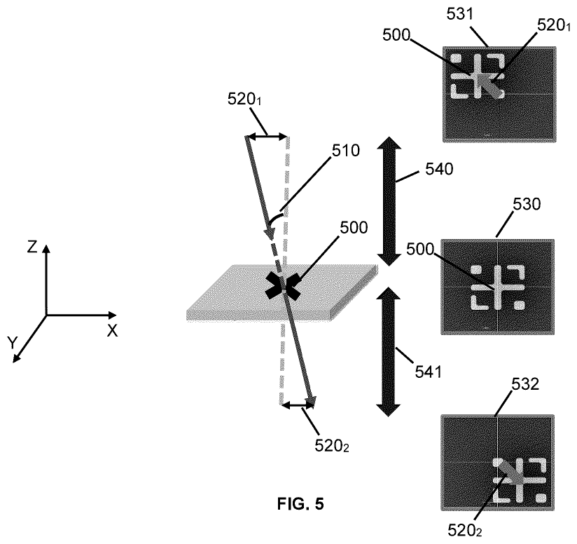

Operation 220 can include using a geometrical relationship between the stray tilt angle, the data D_{ΔZ} informative of a displacement of the target in the set of images and the variation of height of the target in the set of images. As visible in FIG. 5, there is a geometrical relationship between the stray tilt angle 510, the displacement (5201 or 5202) of the target 500 between the first image 530 and the second image (531 or 532), and the height variation (540 or 541) of the target between acquisition of the first image and acquisition of the second image. In particular, the following relationship can be used:

$$θ = a {tan}^{- 1} ( \frac{Δ R}{Δ Z} ) \qquad Equation 1$$

In Equation 1, θ corresponds to the stray tilt angle, ΔR corresponds to the amplitude of the displacement of the target between the first image and the second image, and ΔZ corresponds to the height variation of the target between the first image and the second image.

Assume that the target has been displaced, between the first image and the second image, along the horizontal X axis by a displacement ΔX, and along the vertical Y axis by a displacement ΔY, then ΔR can be expressed as follows: ΔR=\sqrt{|ΔX|²+|ΔY|²}.

Assume that the target has been displaced, between the first image and the second image, along the height axis (Z axis) between a first height position Z₁ and a second height position Z₂, then ΔZ can be expressed as follows: ΔZ=|Z₂−Z₁|.

The stray tilt angle of the beam can be determined using the equation provided above. The stray tilt angle can be output to an operator and/or provided to another computerized system.

According to some embodiments, the set of images obtained at operation 200, comprises images I₁ to I_{N}, with N≥2, wherein each image Iᵢ of the set of images has been acquired capturing the target at a height position Hi which differs from a height position Hⱼ at which other images Iⱼ of the set of images have been acquired, with i different from j. It is possible to modify the height by a fixed step, but this is not mandatory. This enables obtaining a distribution linking the displacement (along the X or Y axis) of the target in the images with the height position of the target. A fitting of the distribution with a model (e.g., linear fitting) enables determining the relationship between the displacement of the target and the height position of the target. This model, together with Equation 1, can be used to obtain an aggregated estimate of the stray tilt angle, based on the various measured displacements and heights. This is not limitative and other methods can be used.

It is also possible to use several times the geometrical relationship of Equation 1 with different pairs of images, thereby obtaining for each pair of images an estimate of the stray tilt angle. An aggregated estimate of the stray tilt angle can be generated (e.g., as average of the different estimate). This is not limitative and other methods can be used.

In some examples, once the stray tilt angle has been determined according to the various methods described herein, metrology measurements can be performed. The metrology measurements can include e.g., CD measurements, overlay measurements, etc. By virtue of the measurement of the stray tilt angle, these metrology measurements are accurate. Indeed, the stray tilt angle impacts the accuracy of metrology measurements. A tilt of 0.1° due to a non-zero stray tilt angle can generate a significant error on the metrology measurements. An accurate determination of the stray tilt angle, as achieved by the methods described herein, improves the accuracy of metrology measurements.

In some examples, measurement of the stray tilt angle can be used to calibrate the beam, in order to have a stray tilt angle equal to zero (or close to zero according to a matching criterion, which can be strict). In some examples, an operator (and/or a computerized system operative to control the electron beam examination system, and/or the electron beam examination system itself) can modify one or more parameters associated with the examination system beam to obtain the desired stray tilt angle. In some examples, the examination system can receive the value of the current stray tilt angle and may automatically modify one or more parameters to obtain the desired stray tilt angle. In particular, the current provided to the coils of the examination system, such as the tilt coils and/of the shift coils (located below the objective lens), can be modified in order to obtain a stray tilt angle equal to zero, or nearly equal to zero.

The method of FIG. 2 enables using a target which is flat (since the method does not require the usage of the profile of the target to determine the stray tilt angle). In addition, even if a non-flat target is used, it is not necessary to know in advance and/or to determine the height profile of the target. The method operates even if there is no a priori knowledge of the height profile of the target, or even if there is a inaccurate knowledge of the height profile of the target.

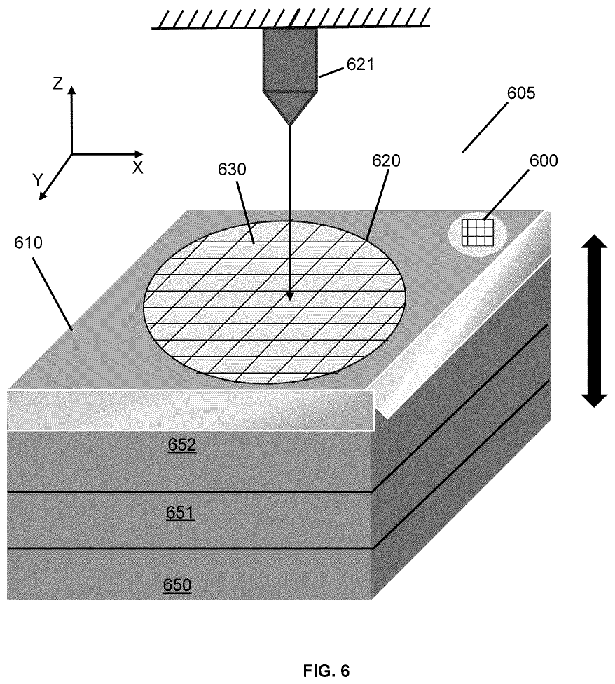

Attention is now drawn to FIG. 6, which describes an example of a target 600 that can be used to determine the stray tilt angle.

An examination system 605 (such as a SEM—this not limitative) generally includes a basement 610, which includes an area 620 dedicated to receiving the specimen (wafer) 630 under examination. During examination of the specimen 630, the specimen 630 can be mechanically coupled to the basement 610, in order to maintain the specimen at a fixed position with respect to the basement 610. One or more mechanical links can be used to affix the specimen 630 to the basement 610.

The basement 610 may be displaced along one or more directions. A first stage 650 can control the translation of the basement 610 along the Z axis, a second stage 651 can control the translation of the basement 610 along the Y axis, and a third stage 652 can control the translation of the basement 610 along the X axis. The first, second, and third stages 650, 651, and 652 may be coupled to the basement 610 or can constitute the bottom part of the basement 610.

In some examples, the target 600 can be located on the basement 610, or on a portion which is mechanically coupled to the basement 610, at a position which differs from the area 610 dedicated to receiving the specimen 630 under examination. A displacement of the basement 610 (along one or more of the axes X, Y and Z) therefore induces both a displacement of the specimen 630 under examination and of the target 600.

In particular, the target 600 can be located on a side (corner) of the basement 610, thereby leaving free the area dedicated to receiving the specimen 630 under examination. As a consequence, it is possible to have simultaneously a specimen 630 loaded in the examination system 605 for enabling examination of the specimen 630 by the examination system 605, and the target 600 present in the examination system for enabling determination of the stray tilt angle.

In some examples, the target 600 can be a target which is permanently present in the examination system. This target 600 can be called a “target island”. As mentioned above, the target 600 can be present on the basement 610, leaving free the area 620 dedicated to receiving a specimen 630 under examination. There is therefore no need to load the target in the examination system each time a new measurement of the stray tilt angle is required, contrary to other solutions which require loading of a tilt wafer to determine the stray tilt angle and unloading of the tilt wafer to enable examination of a specimen by the examination system.

In general, the target 600 has smaller dimensions than the specimen 630 under examination. This is not limitative. Note that the target 600 can be used for other purposes, if this is required.

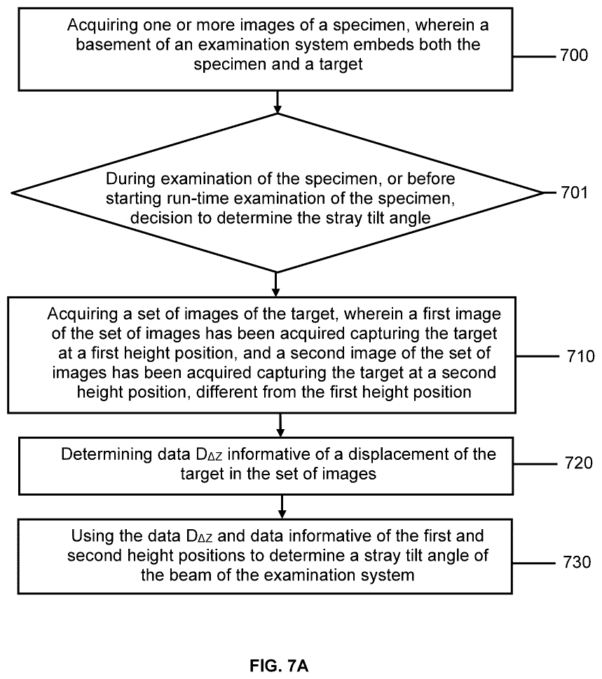

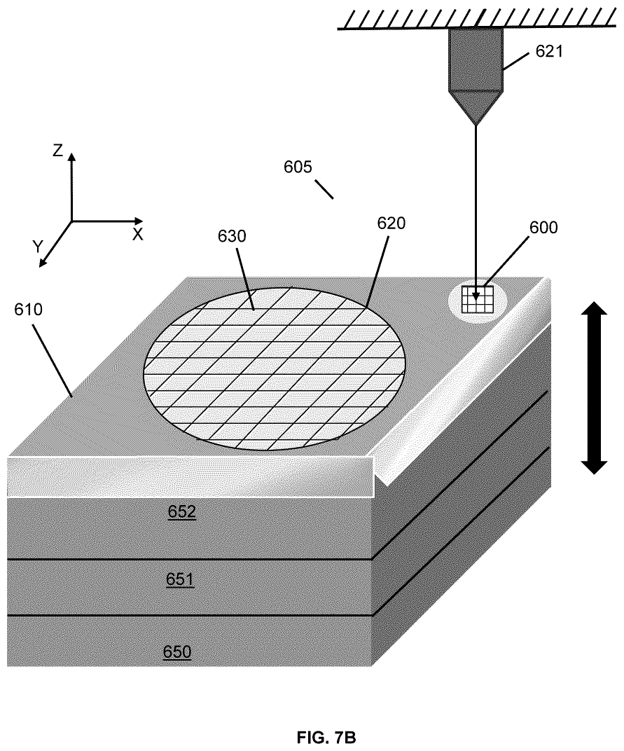

Attention is now drawn to FIG. 7A, which describes a method of determining the stray tilt angle, which can use the architecture of FIG. 6.

Assume that the basement 610 of the examination system includes the specimen 630 loaded on the area 620 of the basement 610 dedicated to receiving the specimen 630 under examination.

The method of FIG. 7A includes acquiring (operation 700) one or more images of the specimen 630 using the examination system (e.g., SEM). This corresponds to a run-time examination phase of the specimen.

It can be decided (operation 701), during examination of the specimen 610, or before starting run-time examination of the specimen 610, to determine the stray tilt angle. This decision can be taken by an operator, who can provide an instruction to the examination system using an interface. Alternatively, the decision can be taken automatically, when one or more conditions are met. The conditions can include e.g. a condition on the time elapsed before the last calibration of the stray tilt angle. When the time elapsed before the last calibration of the stray tilt angle is above a threshold, a calibration of the stray tilt angle can be triggered. In some examples, each time it is detected that a new specimen is loaded for its examination, a calibration of the stray tile angle can be triggered. This is not limitative.

Responsive to the decision of determining the stray tilt angle, the method of FIG. 7A further includes acquiring (operation 710) a set of images of the target 600. This can include displacing the basement 610 to enable the beam to be mainly directed towards the target 600 (instead of being directed towards the specimen 610). Alternatively, or in addition, the column 621 controlling the beam can be controlled to orient the beam on the target 600. A non-limitative example is illustrated in FIG. 7B.

As already explained with reference to FIG. 2, a first image of the set of images has been acquired capturing the target 600 at a first height position, and a second image of the set of images has been acquired capturing the target 600 at a second height position, different from the first height position.

The method of FIG. 7A further includes determining (operation 720) data DAz informative of a displacement of the target in the set of images.

The method of FIG. 7A further includes using (operation 730) the data DAz and data informative of the first and second height positions (in particular, the difference between the first and second height positions) to determine a stray tilt angle of the beam of the examination system. Operation 730 is similar to operation 220 described above.

Once the stray tilt angle has been determined, it is possible to revert to the examination of the specimen 630 (or of another specimen which has been loaded on the basement 610 in replacement of the specimen 630). This can include displacing the basement 610 to enable the beam to be mainly directed towards the specimen 630 (instead of being directed towards the target 600). Alternatively, or in addition, the column 621 controlling the beam can be controlled to orient the beam on the specimen 630.

The method of FIG. 7A enables switching from a first mode in which the target is used to determine the stray tilt angle, to a second mode in which examination of a specimen is performed, in a quick and efficient way. It is possible to switch from the first mode to the second mode, or conversely, since the specimen and the target are located on the same basement. The switch can be triggered by an operator and/or automatically, by the examination system, or by a computerized system controlling the examination system.

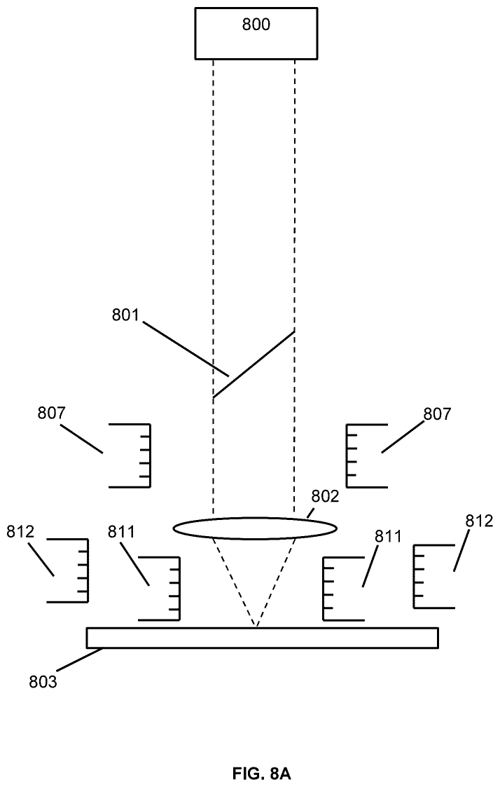

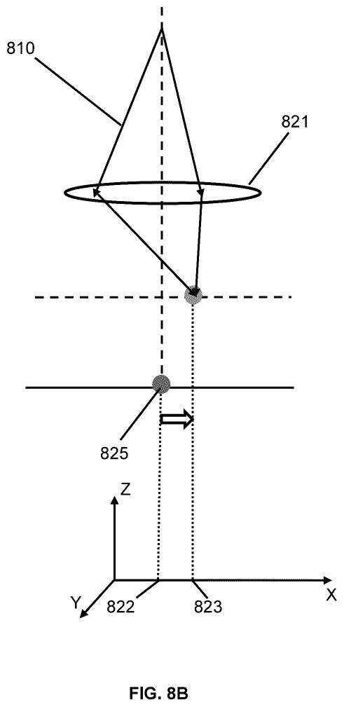

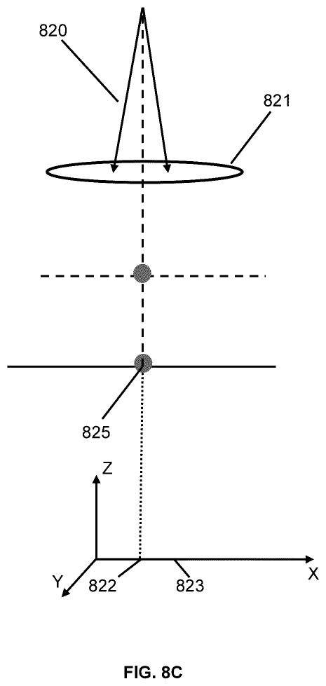

Attention is now drawn to FIG. 8A.

In an electron beam examination tool (such as examination tool(s) 101 and/or 102), a radiation source 800 emits an electron beam, which passes through a first beam splitter 801 and is focused by objective lens 802 onto a region of specimen 803. Tilt coils 807 (also called objective lens coils) can be used to control the deflection of the electron beam. Note that additional coils (e.g. shift coils 811 and tilt coils 813) can be present below the objective lens 802, and impact the stray tilt angle of the electron beam.

FIG. 8B illustrates an example of an uncalibrated state, in which the electron beam 810 impinges the objective lens 821 at an actual position which deviates from the center of the objective lens 821. As a consequence, the focal point of the electron beam is translated with respect to the target 825 in the X-Y plane. When the height position of the target is modified (along the Z axis), the position of the target is translated from one image to the other in the X-Y plane.

FIG. 8C illustrates a calibrated state, in which the electron beam 810 impinges the objective lens 821 at its center. When the height position of the target 825 is modified (along the Z axis), there is no drift of the target due to an uncalibrated position of the electron beam 810 with respect to the objective lens.

Applicant has discovered that it can be beneficial to first perform a calibration of the position of the electron beam with respect to the objective lens, before determining the stray tilt angle using the methods described herein, which rely on a modification of the height of the target. Indeed, if the position of the electron beam is not calibrated with respect to the objective lens, a modification of the height of the target may generate a drift, which is not caused by the stray tilt angle, but which is caused by the uncalibrated state of the electron beam with respect to the objective lens. As a consequence, this may introduce an error in the estimate of the stray tilt angle. This is however not limitative and the various methods described herein can be performed without performing the calibration of the position of the electron beam with respect to the objective lens. Note that these principles can be applied similarly to the beam of an optical examination system.

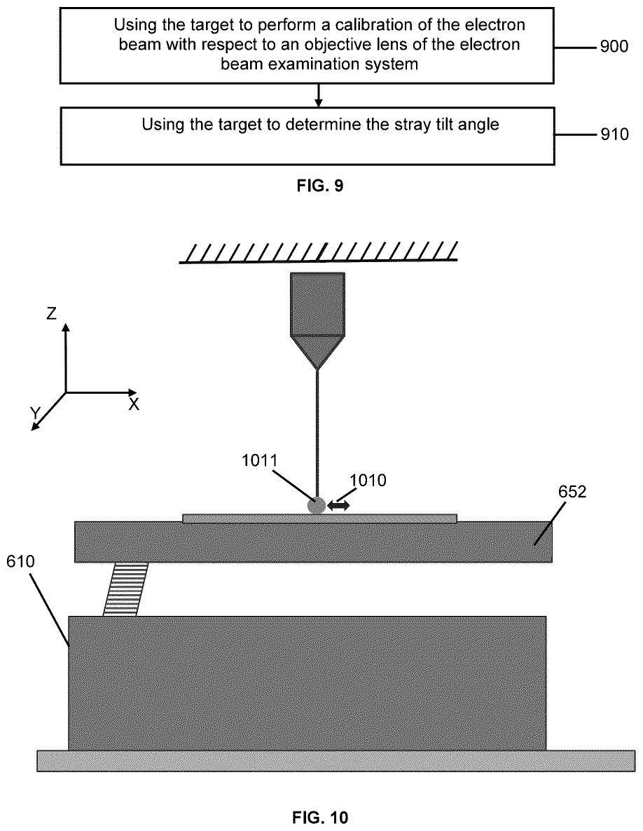

FIG. 9 illustrates a method which relies on these principles and includes using (operation 900) the target to perform a calibration of the beam (e.g., electron beam, or optical beam) with respect to an objective lens of the examination system. This calibration can include aligning a focal point of the electron beam with an axis of symmetry of the objective lens, according to a matching criterion. In some examples, it can include making the focal point of the electron beam coincide with the target.

Calibration of the electron beam with respect to the objective lens can rely on different methods. In some examples, the landing energy of the electron beam is modified. For each landing energy, an image of a wafer is acquired. Note that the wafer can correspond to the target 600 mentioned above. The drift of the wafer between the images is determined, using cross-correlation methods, image recognition algorithms, or other adapted methods. It is possible to use this drift, and a model linking the drift to the currents of the coils 807 controlling the position of the electron beam, to determine a modification of the currents of the coils 807 enabling the electron beam to impinge the objective lens at its center. The model can be generated during a training phase. A non-limitative example of a method enabling calibrating the position of the electron beam with respect to the objective lens is described in U.S. Pat. No. 7,335,893, which is incorporated herein by reference in its entirety.

Calibration of the position of the electron beam with respect to the objective lens can be performed with an accuracy which may be tight, in order to reduce, as much as possible, the error in the stray tilt angle. In some examples, the accuracy required by the matching criterion can be selected such that the error in the calibration of the position of the electron beam is equal to or smaller than 0.2 nm. This value is not limitative and other values can be used (in addition, as mentioned above, it is possible to determine the stray tilt tangle without performing this calibration). Note that the calibration of the electron beam with respect to the objective lens does not necessarily mean that the stray tilt angle will be equal to zero. Indeed, additional coils are present below the objective lens and impact the deflection of the electron beam, and, in turn, the value of the stray tilt angle.

The method further includes (operation 910) using the target to determine the stray tilt angle. Operation 910 can rely on the method of FIG. 2.

Once the stray tilt angle has been determined, the method can include controlling the shift coils and/or the tilt coils in order to enable the stray tilt angle to be equal to zero, or nearly equal to zero. Note that the process of calibrating the currents provided to the shift coils and/or to the tilt coils, in order to obtain a stray tilt angle nearly equal to zero, can be iterative.

As can be understood from the method of FIG. 9, both the calibration of the electron beam with respect to the objective lens, and the determination of the stray tilt angle can be performed by using the same target, which is efficient.

In some examples, the electron beam examination system can be controlled to switch from a first mode to a second mode. In the first mode, the electron beam of the electron beam examination system is oriented towards the target to calibrate the position of the electron beam with respect to the objective lens, and then to determine the stray tilt angle. In the second mode, the electron beam is oriented towards the specimen (located on the area 620) for its examination. It is possible to switch from the first mode to the second mode, or conversely, in an efficient way, in real-time, and during run-time examination of the specimen. These principles can be applied similarly to the beam of an optical examination system.

Attention is now drawn to FIG. 10.

Applicant has discovered that the motion induced by the stage 652 of basement 610 (on which the target is mounted) to modify the height of the target, is not always perfectly vertical. As visible in FIG. 10, when the stage 652 modifies the height of the target 1011, it can occur that this stage 652 also encounters a motion along a direction different from the height direction (such as in the X and/or Y direction corresponding to the horizontal and vertical directions in the plane of the target). This undesirable motion of the stage 652 induces a drift 1010 of the target along the X and/or Y direction, which, in turn, induces a drift of the target in the images which is not linked to the stray tilt angle. This generates an error in the estimate of the stray tilt, since most of the methods described herein rely on a height variation of the target to determine the stray tilt angle.

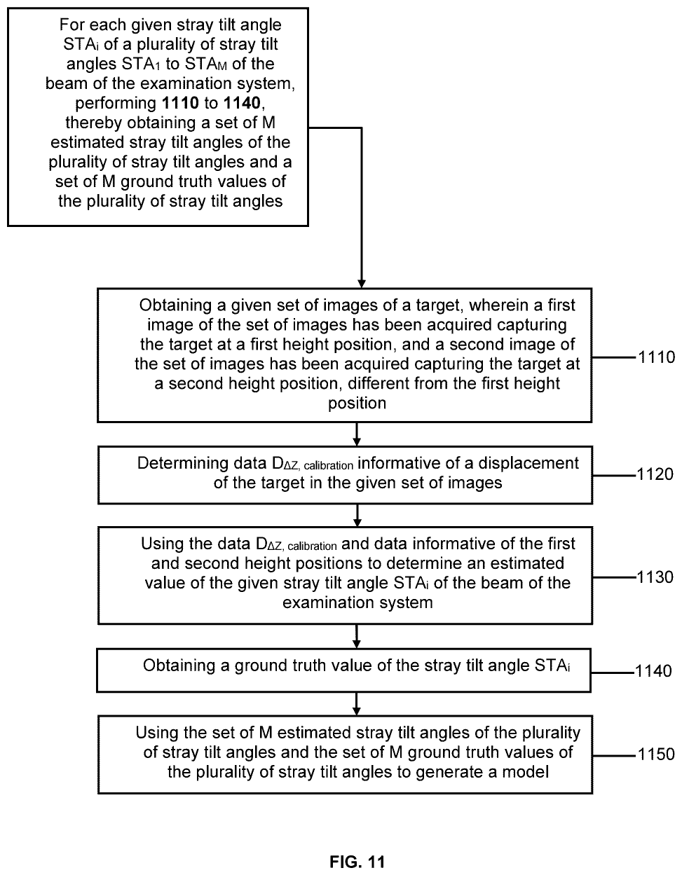

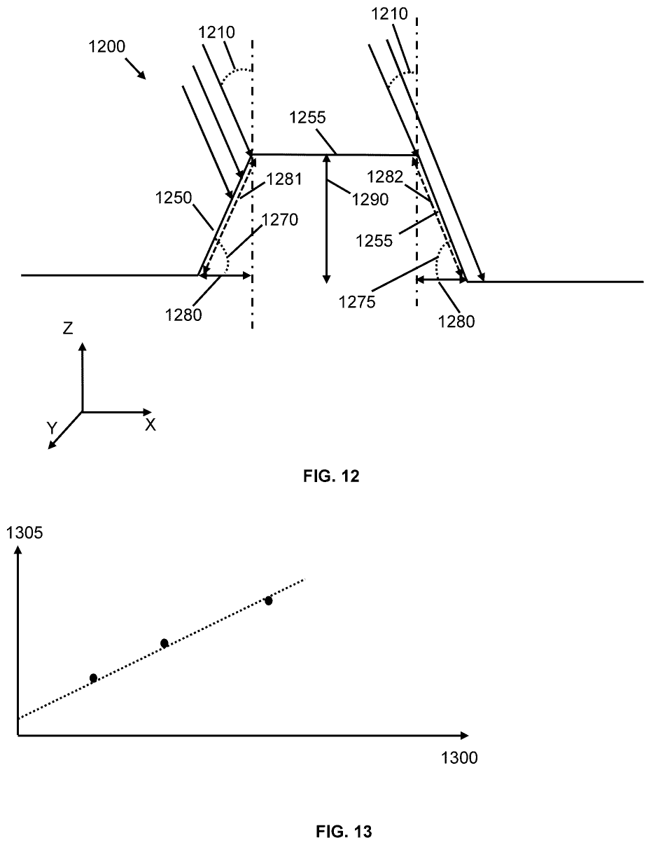

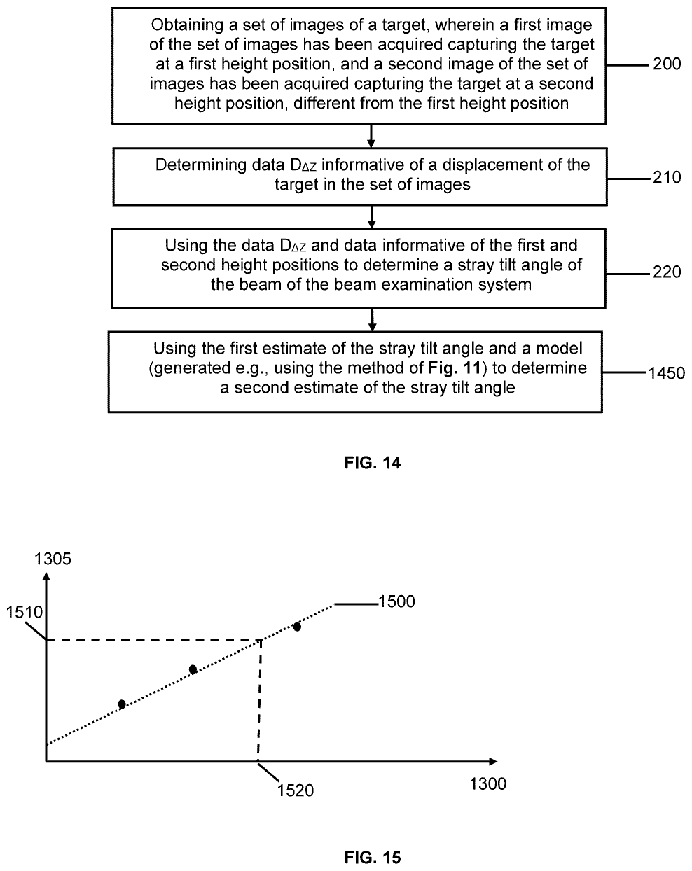

The method of FIG. 11 proposes a solution to compensate, at least partially, error(s) in the determination of the stray tilt angle. In particular, the method of FIG. 11 proposes to use a model to compensate, at least partially, an error in said estimate of the stray tilt angle, caused (at least) by a motion of the stage which moves the basement along the height direction. Note that this model can be used to correct other error(s) in the estimate of the stray tilt angle.

The method of FIG. 11 includes performing a plurality of operations, for each given stray tilt angle STAᵢ of the beam of a plurality of stray tilt angles STA₁ to STA_{M} (with M≥2 or M≥3) of the beam. Modification of the stray tilt angle of the beam can be performed by modifying the current provided to one or more coils (see e.g. coils 811, 812) of the examination system, which impact the deflection of the electron beam.

For each given stray tilt angle STAᵢ of the electron beam, the method of FIG. 11 includes obtaining (operation 1110) a given set of images of a target. The target may correspond to the target 600 (located on the basement of the examination system, which is able to receive a specimen for its examination). This is however not limitative. The given set of images has been acquired by an electron beam examination system, such as the electron beam examination system 101 or 102.

The given set of images includes at least two images. The given set of images can include more than two images. A first image of the target has been acquired capturing the target located at a given first height position. A second image of the target has been acquired capturing the target at a given second height position, different from the given first height position. Note that it is possible to obtain N images I₁ to I_{N} of the target, with N≥2, wherein each image Iᵢ of the set of images has been acquired capturing the target at a height position Hi which differs from a height position Hⱼ at which other images Iⱼ of the set of images have been acquired, with i different from j.

The method of FIG. 11 further includes (operation 1120) determining data D_{ΔZ, calibration} informative of a displacement of the target in the given set of images. This operation 1120 is similar to operation 210.

The method of FIG. 11 further includes (operation 1130) using the data D_{ΔZ, calibration} and data informative of the given first and second height positions (or data informative of the N height positions) to determine an estimated value of the given stray tilt angle of the electron beam of the electron beam examination system. This operation 1130 is similar to operation 220. As mentioned above with respect to operation 220, determination of an estimate value of the stray tilt angle can include using a geometrical relationship between the stray tilt angle, the data D_{ΔZ, calibration} informative of a displacement of the target in the given set of images, and the variation of height of the target in the set of images (in particular, Equation 1 can be used). If a plurality of images Iᵢ to I_{N}, with N≥2, has been obtained, it is possible to use several times the geometrical relationship with different pairs of images, thereby obtaining for each pair of images an estimate of the stray tilt angle. An aggregated estimate (this aggregate includes e.g., averaging—this is not limitative) of the stray tilt angle can be determined.

Since operations 1110, 1120 and 1130 are performed for a plurality of M different stray tilt angles, the method enables obtaining a set of M estimated stray tilt angles of the M stray tilt angles.

The method of FIG. 11 further includes obtaining (operation 1140) ground truth values of the M stray tilt angles. Ground truth values correspond to values which are assumed to accurately reflect the true values of the M stray tilt values.

In some examples, determination of the ground truth values of the stray tilt angles can include using a tilt wafer (see tilt wafer 1200 in FIG. 12) with a height profile including at least one slope. This is however not limitative. In this method, the height profile must be known a priori. In the example of FIG. 12, the tilt wafer 1200 includes a first slope 1250, a top part 1255, and a second slope 1260. The tilt wafer 1200 is assumed to be symmetric, that it to say that it is assumed that the first slope and the second slope have the same angular inclination, with opposite signs (see angular inclination 1270 and angular inclination 1275), and the projections of the first and second slopes (along a horizontal axis X) extend along the same horizontal distance 1280. The stray tilt angle 1210 can be estimated using the following formula:

$${θ}_{G T} = arctan ( \frac{{E}_{WL} - {E}_{WR}}{2 h} ) \qquad Equation 2$$

In Equation 2, θ_{GT} is an estimate of the stray tilt angle (considered as the ground truth value), E_{WL} is the length (see reference 1281) of the first slope 1250, E_{WR} is the length (see reference 1282) of the second slope 1260, and h is the height (see reference 1290) of the top part 1255 of the tilt wafer 1200.

The method of FIG. 11 further includes generating (operation 1150) a model which models a relationship between the estimated values of the stray tilt angles to the ground truth values of the stray tilt angle values. This model can be an affine function, but this is not limitative. Operation 1150 includes using the set of M estimated stray tilt angles of the plurality of stray tilt angles and the set of M ground truth values of the plurality of stray tilt angles. In particular, operation 1150 can include fitting a function which models the relationship between the set of M estimated stray tilt angles of the plurality of stray tilt angles and the set of M ground truth values of the plurality of stray tilt angles. This fitting includes determining the coefficients of the function. For an affine function (which is expressed as y=ax+b), the coefficients to be determined are “a” (the slope) and “b” (intercept).

A non-limitative example of the model is illustrated in FIG. 13.

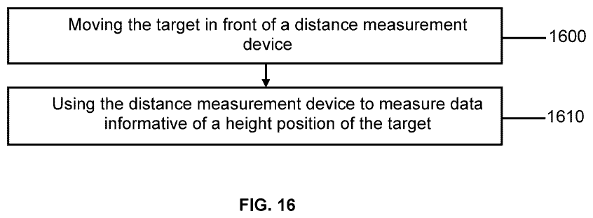

In FIG. 13, the X axis 1300 corresponds to the ground truth values of the stray tilt angle (as obtained at operation 1140) and the Y axis 1305 corresponds to the estimate values of the stray tilt angle (as obtained at operation 1130 or operation 220). An affine function is fit (y=ax+b), in order to obtain the coefficients “a” and “b”. It is desired that “a” be close to 1. Applicant has discovered that a tight calibration of the beam with respect to the objective lens improves the prospects that the coefficient “a” will be close to 1. Similarly, an accurate knowledge of the actual height of the target improves the prospects that the coefficient “a” will be close to 1. Determination of the actual height of the target can rely on the method of FIG. 16 described hereinafter. The coefficient “b” is not always equal to zero because the motion induced by the stage 652 of the basement 610 (on which the target is mounted) to modify the height of the target is not always perfectly vertical, as explained with reference to FIG. 10. Note that other types of models (which are not necessarily affine functions) can be used.

Once the model has been generated (during the “training phase” described with reference to FIG. 11), it can be used in prediction, as illustrated in FIGS. 14 and 15.

The method of FIG. 14 includes performing operations 200, 210 and 220 of FIG. 2, in order to obtain a first estimate of the stray tilt angle of the electron beam of the examination system. This first estimate is obtained by moving the target vertically, measuring its displacement in the images, and using a relationship (such as Equation 1) to estimate the stray tilt angle. As mentioned above, this first estimate may be associated with a small inaccuracy, due for example to the motion induced by the stage 652 of the basement 610 (on which the target is mounted) to modify the height of the target, which is not always perfectly vertical. Note that the small inaccuracy of the first estimate may be caused by other factor(s).

The method of FIG. 14 further includes using (operation 1450) the first estimate of the stray tilt angle and the model generated using the method of FIG. 11 to determine a second estimate of the stray tilt angle. Note that the second estimate of the stray tilt angle is expected to be more accurate than the first estimate of the stray tilt angle.

As mentioned above, the model links each value of the estimate of the stray tilt angle to a corresponding ground truth value of the stray tilt angle. Assume for example that the model F is expressed as follows: STAₑₛₜᵢₘₐₜₑ=F(STA_{ground truth}), in which STAₑₛₜᵢₘₐₜₑ is the estimate of the stray tilt angle and STA_{ground truth} is the ground truth value of the stray tilt angle. Therefore, the second estimate STA_{second estimate} of the stray tilt angle can be obtained from the first estimate STA_{first estimate} of the stray tilt angle as follows: STA_{second estimate}=F⁻¹(STA_{first estimate}).

A non-limitative example is illustrated in FIG. 15.

Assume that the model 1500 has been generated and that a first estimate 1510 of the stray tilt angle has been obtained using the method of FIG. 2. The model (generated using the method of FIG. 11) is used to determine a second estimate 1520 of the stray tilt angle, which can be selected as corresponding to the point, on the curve of the model, which has the same abscissa as the first estimate 1510 of the stray tilt angle.

In some examples in which the model is an affine function, operation 1450 can include subtracting, from the first estimate, the intercept coefficient of the affine function, to generate the second estimate of the stray tilt angle.

Attention is drawn to FIG. 16, which depicts a method of determining the actual height position of the target.

Note that the method of FIG. 16 is only an example and any other adapted method can be used to measure the height position of the target. For example, an encoder which measures the position of the basement on which the target is located can be used. In other examples, any sensor adapted to measure a distance (laser, ultrasonic sensor, etc.) can be used to measure the height of the target. A combination of these methods can be performed, or other methods can be used.

As mentioned above with reference to FIG. 6, the target may be located on a basement 610 of the examination system, which is moveable at least along the height direction. The examination system may provide information of the height of the area 620 dedicated to receiving the specimen (wafer) 630 under examination. However, it can occur that the height position of the wafer differs from the height position of the area 620. In order to calibrate the height position of the target, the method of FIG. 16 can include moving (operation 1600) the target in the X-Y plane, in order for the target to be in front of a distance measurement device of the examination system along the Z axis, and using (operation 1610) the distance measurement device to measure data informative of a height position of the target. In some examples, the distance measurement device includes a laser, and the distance is measured based on the time for the laser to perform a round-trip (back and forth displacement). This enables determining the relationship between the height position of the basement 610 (which may be provided by the electron beam examination system) and the actual height position of the target. Note that this calibration of the height of the target is generally performed before estimating the stray tilt angle, as explained in the various methods described herein.

In the detailed description, numerous specific details have been set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the aforementioned discussions, it is appreciated that throughout the specification discussions utilizing terms such as “obtaining”, “determining”, “performing”, “using”, “estimating”, “training”, or the like, refer to the action(s) and/or process(es) of at least one processing circuitry that manipulates and/or transforms data into other data, said data represented as physical, such as electronic, quantities and/or said data representing the physical objects.

The terms “computer” or “computer-based system” should be expansively construed to include any kind of hardware-based electronic device with a data processing circuitry (e.g., digital signal processor (DSP), a GPU, a TPU, a field programmable gate array (FPGA), an application specific integrated circuit (ASIC), microcontroller, microprocessor etc.), including, by way of non-limiting example, the computer-based system 103 of FIG. 1 and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together. The one or more processors can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

It is to be noted that while the present disclosure refers to the processing circuitry 104 being configured to perform various functionalities and/or operations, the functionalities/operations can be performed by the one or more processors of the processing circuitry 104 in various ways. By way of example, the operations described hereinafter can be performed by a specific processor, or by a combination of processors. The operations described hereinafter can thus be performed by respective processors (or processor combinations) in the processing circuitry 104, while, optionally, at least some of these operations may be performed by the same processor. The present disclosure should not be limited to be construed as one single processor always performing all the operations.

The term “specimen” used in this specification should be expansively construed to cover any kind of wafer, masks, and other structures, combinations and/or parts thereof used for manufacturing semiconductor integrated circuits, magnetic heads, flat panel displays, and other semiconductor-fabricated articles.

The term “examination” used in this specification should be expansively construed to cover any kind of metrology-related operations as well as operations related to detection and/or classification of defects in a specimen during its fabrication. Examination is provided by using non-destructive examination tools during or after manufacture of the specimen to be examined. By way of non-limiting example, the examination process can include runtime scanning (in a single or in multiple scans), sampling, reviewing, measuring, classifying and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes, atomic force microscopes, optical inspection tools, etc.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately, or in any suitable sub-combination. In the following detailed description, numerous specific details are set forth in order to provide a thorough understanding of the methods and apparatus.

In embodiments of the presently disclosed subject matter, fewer, more, and/or different stages than those shown in the methods of FIGS. 2, 7A, 9, 11, 14, and 16 may be executed. In embodiments of the presently disclosed subject matter, one or more stages illustrated in the methods of FIGS. 2, 7A, 9, 11, 14, and 16 may be executed in a different order, and/or one or more groups of stages may be executed simultaneously.

It is to be understood that the invention is not limited in its application to the details set forth in the description contained herein or illustrated in the drawings.

It will also be understood that the system according to the invention may be, at least partly, implemented on a suitably programmed computer. Likewise, the invention contemplates a computer program being readable by a computer for executing the methods of the invention. The invention further contemplates a non-transitory computer-readable memory tangibly embodying a program of instructions executable by the computer for executing the methods of the invention.

The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

What is claimed is:

1. A system comprising one or more processing circuitries configured to:
for each given stray tilt angle of a beam of an examination system, of a plurality of stray tilt angles:
obtain a given set of images of the target,
wherein a given first image of the given set of images has been acquired capturing the target at a given first height position, and a second image of the given set of images has been acquired capturing the target at a given second height position, different from the first height position, determine data D_{ΔZ, calibration} informative of a displacement of the target in the given set of images, and
use the data D_{ΔZ, calibration} and data informative of the given first and second height positions to determine a given estimated stray tilt angle of the electron beam,
thereby obtaining a plurality of estimated stray tilt angles of the plurality of stray tilt angles, and
use the plurality of stray tilt angles, or ground truth values of said plurality of stray tilt values, and the plurality of estimated stray tilt angles to generate a model.

2. The system of claim 1, configured to:
obtain a set of images of the target,
wherein the set of images has been acquired by the examination system,
wherein a first image of the set of images has been acquired capturing the target at a first height position, and a second image of the set of images has been acquired capturing the target at a second height position, different from the first height position,
determine data D_{ΔZ} informative of a displacement of the target in the set of images,
use the data D_{ΔZ} and data informative of the first and second height positions to determine a first estimate of a stray tilt angle of a beam of the examination system, and
use the model and the first estimate to generate a second estimate of the stray tilt angle.

3. A system comprising one or more processing circuitries configured to:
obtain a set of images of a target,
wherein the set of images has been acquired by an examination system,
wherein a first image of the set of images has been acquired capturing the target at a first height position, and a second image of the set of images has been acquired capturing the target at a second height position, different from the first height position,
determine data D_{ΔZ} informative of a displacement of the target in the set of images, and
use the data D_{ΔZ} and data informative of the first and second height positions to determine a stray tilt angle of a beam of the examination system.

4. The system of claim 3, wherein said set of images has been obtained after a calibration of the beam of the examination system with respect to an objective lens of the examination system, wherein said calibration uses said target.

5. The system of claim 4, wherein said calibration comprises aligning a focal point of the beam with an axis of symmetry of the objective lens, according to a matching criterion.

6. The system of claim 4, wherein said calibration is associated with an accuracy equal to or smaller than 0.2 nm.

7. The system of claim 3, wherein the set of images comprises images I₁ to I_{N}, with N≥2, wherein each image Iᵢ of the set of images has been acquired capturing the target at a height position Hi which differs from a height position Hⱼ at which other images Iⱼ of the set of images have been acquired, with i different from j.

8. The system of claim 3, configured to use a geometrical relationship between the stray tilt angle, the data D_{ΔZ} informative of a displacement of the target in the set of images, and data informative of the first and second height positions, to determine said stray tilt angle.

9. The system of claim 3, wherein the examination system comprises an element operative to move the target along a height direction, wherein the system is configured to use a model to compensate, at least partially, an error in said estimate of the stray tilt angle, caused at least by a motion of said element along a direction different from the height direction.

10. The system of claim 3, wherein (i) or (ii) is met:
(i) the examination system comprises a basement comprising an area dedicated to receiving a specimen under examination, wherein the target is located on the basement, or on a portion coupled to the basement;
(ii) the examination system comprises a basement comprising an area dedicated to receiving a specimen under examination, wherein the target is permanently located on the basement, or on a portion coupled to the basement.

11. The system of claim 3, wherein (i) or (ii) is met:
(i) the system is configured to control the examination system to switch between a first mode and a second mode, wherein, in the first mode, the beam is oriented towards the target to determine the stray tilt angle, and in the second mode, the beam is oriented towards a specimen for its examination, wherein the specimen and the target are associated with a same basement;
(ii) the examination system is operative to switch between a first mode and a second mode, wherein, in the first mode, the beam is oriented towards the target to determine the stray tilt angle, and in the second mode, the beam is oriented towards a specimen for its examination, wherein the specimen and the target are associated with a same basement.

12. The system of claim 3, wherein the target has a flat pattern.

13. The system of claim 3, configured to:
use the data D_{ΔZ} and data informative of the first and second height positions to determine a first estimate of the stray tilt angle of the beam of the examination system, and
use a model and the first estimate to generate said estimate of the stray tilt angle.

14. The system of claim 13, wherein the model models an error of an estimate of the stray tilt angle, when said estimate is obtained based on height variation of the target and displacement of the target in images associated with said height variation.

15. The system of claim 13, wherein the model models a relationship between estimated stray tilt angles of a plurality of stray tilt angles and a plurality of ground truth values of said plurality of stray tilt angles.

16. The system of claim 3, configured to use a distance measurement device to determine data informative of a height position of the target.

17. The system of claim 3, configured to:
for each given stray tilt angle of the beam of the examination system, of a plurality of stray tilt angles:
obtain a given set of images of the target,
wherein a given first image of the given set of images has been acquired capturing the target at a given first height position, and a second image of the given set of images has been acquired capturing the target at a given second height position, different from the first height position,
determine data D_{ΔZ, calibration} informative of a displacement of the target in the given set of images, and
use the data D_{ΔZ, calibration} and data informative of the given first and second height positions to determine a given estimated stray tilt angle of the beam of the examination system,
thereby obtaining a plurality of estimated stray tilt angles of the plurality of stray tilt angles, and
use the plurality of stray tilt angles, or ground truth values of said plurality of stray tilt values, and the plurality of estimated stray tilt angles to generate a model.

18. The system of claim 17, configured to use the data D_{ΔZ} and data informative of the first and second height positions to determine a first estimate of the stray tilt angle of the beam of the examination system, and use the model and the first estimate to generate said estimate of the stray tilt angle.

19. The system of claim 17, wherein the ground truth stray tilt angles values have been obtained using a wafer with a height profile including a first slope and a second slope.

20. A non-transitory computer readable medium comprising instructions that, when executed by at least one or more processing circuitries, cause the at least one or more processing circuitries to obtain a set of images of a target, wherein the set of images has been acquired by an examination system, wherein a first image of the set of images has been acquired capturing the target at a first height position, and a second image of the set of images has been acquired capturing the target at a second height position, different from the first height position, determine data D_{ΔZ} informative of a displacement of the target in the set of images, and use the data D_{ΔZ} and data informative of the first and second height positions to determine a stray tilt angle of a beam of the examination system.
